(19) United States
(12) Patent Application Publication
(10) Pub. No.: US 2025/0248103 A1
(43) Pub. Date: Jul. 31, 2025

(54) SEMICONDUCTOR DEVICE AND MANUFACTURING METHOD THEREOF

(71) Applicant: United Microelectronics Corp., Hsin-Chu City (TW)

(72) Inventors: Jin-Yan Chiou, Tainan (TW); Wei-Chuan Tsai, Changhua County (TW); Hsiang-Wen Ke, Kaohsiung City (TW); Yen-Tsai Yi, Tainan City (TW)

(21) Appl. No.: 18/623,065

(22) Filed: Apr. 1, 2024

(30) Foreign Application Priority Data
Jan. 29, 2024 (TW) 113103293

(51) Int. Cl. H01L 29/423; H01L 21/28; H01L 29/66

(52) U.S. Cl. CPC H10D 64/517; H01L 21/28052; H10D 64/021; H10D 64/514

(57) ABSTRACT

A manufacturing method of a semiconductor device includes the following steps. A semiconductor substrate is provided, and a gate oxide layer, a gate structure, and a spacer structure are formed on the semiconductor substrate. The gate oxide layer is located between the gate structure and the semiconductor substrate in a vertical direction, and the spacer structure is located on a sidewall of the gate structure. A SiCoNi process is performed, and a ratio of nitrogen trifluoride (NF₃) to ammonia (NH₃) used in the SiCoNi process is greater than or equal to 0.35 and less than or equal to 0.4. A nickel silicide layer is formed in the semiconductor substrate after the SiCoNi process, and a part of the nickel silicide layer is located under the spacer structure in the vertical direction.

### BACKGROUND OF THE INVENTION

### 1. Field of the Invention

The present invention relates to a semiconductor device and a manufacturing method thereof, and more particularly, to a semiconductor device including a gate oxide layer and a manufacturing method thereof.

### 2. Description of the Prior Art

In the integrated circuits, transistors may be different from one another in structure for different operation voltages. For example, the transistors for relatively low operation voltage may be applied in core devices, input/output (I/O) devices, and so on. The transistors capable of high voltage processing may be applied in high operation voltage environment such as CPU power supply, power management system, AC/DC converter, and power amplifier. In addition, the operation voltage of the transistor unit may be changed by modifying the thickness of the gate oxide layer generally, but the manufacturing conditions of other parts will be influenced by the thicker gate oxide layer. Therefore, how to improve the operation performance of the transistor structure through the design of structure and/or the design of the manufacturing process is a continuous issue for those in the related fields.

### SUMMARY OF THE INVENTION

A semiconductor device and a manufacturing method thereof are provided in the present invention. A range of a ratio of nitrogen trifluoride (NF₃) to ammonia (NH₃) used in a SiCoNi process is controlled for suppressing lateral diffusion of a nickel silicide layer formed subsequently, and the operation performance of the semiconductor device may be improved accordingly.

According to an embodiment of the present invention, a manufacturing method of a semiconductor device is provided. The manufacturing method includes the following steps. A semiconductor substrate is provided, and a gate oxide layer, a gate structure, and a spacer structure are formed on the semiconductor substrate. The gate oxide layer is located between the gate structure and the semiconductor substrate in a vertical direction, and the spacer structure is located on a sidewall of the gate structure. A SiCoNi process is performed, and a ratio of nitrogen trifluoride (NF₃) to ammonia (NH₃) used in the SiCoNi process is greater than or equal to 0.35 and less than or equal to 0.4. After the SiCoNi process, a nickel silicide layer is formed in the semiconductor substrate, and a part of the nickel silicide layer is located under the spacer structure in the vertical direction.

According to an embodiment of the present invention, a semiconductor device is provided. The semiconductor device includes a semiconductor substrate, a gate structure, a gate oxide layer, a spacer structure, and a nickel silicide layer. The gate structure is disposed on the semiconductor substrate. The gate oxide layer is disposed between the gate structure and the semiconductor substrate in a vertical direction, and the spacer structure is disposed on a sidewall of the gate structure. The nickel silicide layer is disposed in the semiconductor substrate, a part of the nickel silicide layer is located under the spacer structure in the vertical direction, and a length of the part of the nickel silicide layer located under the spacer structure in a horizontal direction is greater than or equal to 4 nanometers and less than or equal to 5 nanometers.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a flow chart of a portion of a manufacturing method of a semiconductor device according to an embodiment of the present invention.

FIGS. 2-5 are schematic drawings illustrating a manufacturing method of a semiconductor device according to an embodiment of the present invention, wherein FIG. 3 is a schematic drawing in a step subsequent to FIG. 2, FIG. 4 is a schematic drawing in a step subsequent to FIG. 3, and FIG. 5 is a schematic drawing in a step subsequent to FIG. 4.

FIG. 6 is a schematic drawing illustrating a semiconductor device according to another embodiment of the present invention.

### DETAILED DESCRIPTION

The present invention has been particularly shown and described with respect to certain embodiments and specific features thereof. The embodiments set forth herein below are to be taken as illustrative rather than limiting. It should be readily apparent to those of ordinary skill in the art that various changes and modifications in form and detail may be made without departing from the spirit and scope of the present invention.

Before the further description of the preferred embodiment, the specific terms used throughout the text will be described below.

The terms “on,” “above,” and “over” used herein should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

The ordinal numbers, such as “first”, “second”, etc., used in the description and the claims are used to modify the elements in the claims and do not themselves imply and represent that the claim has any previous ordinal number, do not represent the sequence of some claimed element and another claimed element, and do not represent the sequence of the manufacturing methods, unless an addition description is accompanied. The use of these ordinal numbers is only used to make a claimed element with a certain name clear from another claimed element with the same name.

The term “etch” is used herein to describe the process of patterning a material layer so that at least a portion of the material layer after etching is retained. When “etching” a material layer, at least a portion of the material layer is retained after the end of the treatment. In contrast, when the material layer is “removed”, substantially all the material layer is removed in the process. However, in some embodiments, “removal” is considered to be a broad term and may include etching.

The term “forming” or the term “disposing” are used hereinafter to describe the behavior of applying a layer of material to the substrate. Such terms are intended to describe any possible layer forming techniques including, but not limited to, thermal growth, sputtering, evaporation, chemical vapor deposition, epitaxial growth, electroplating, and the like.

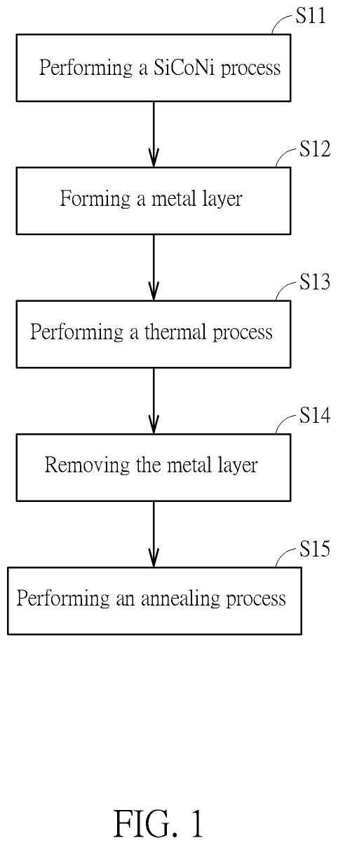

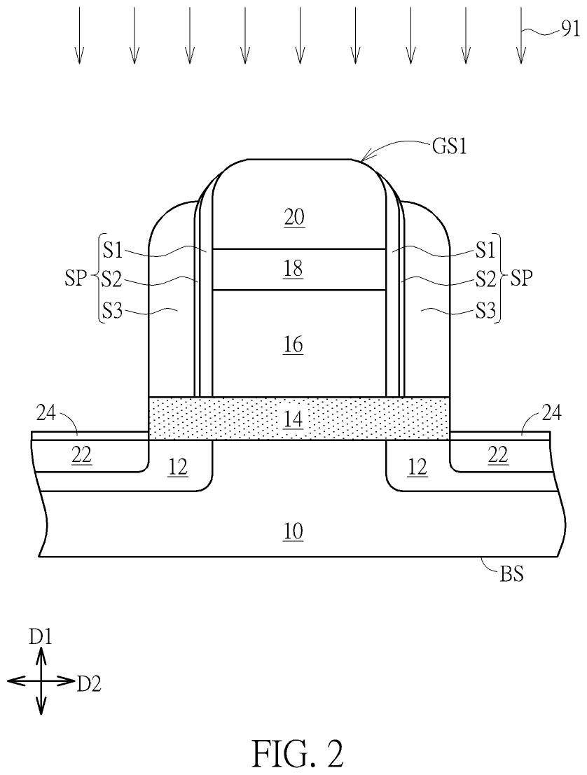

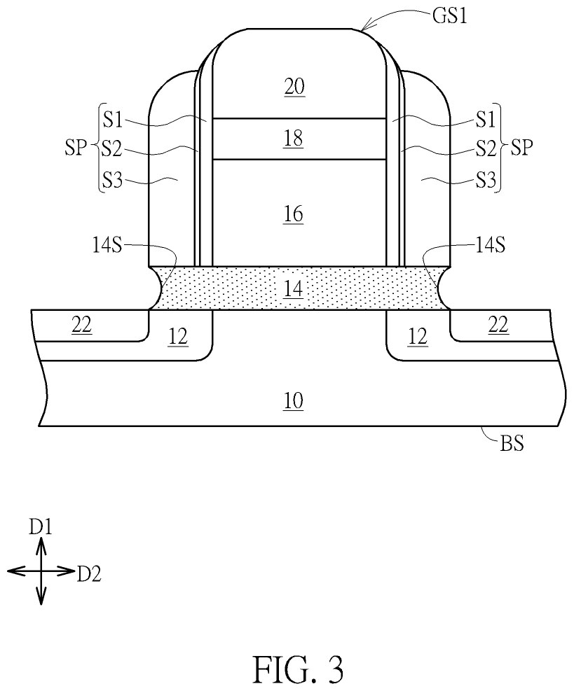

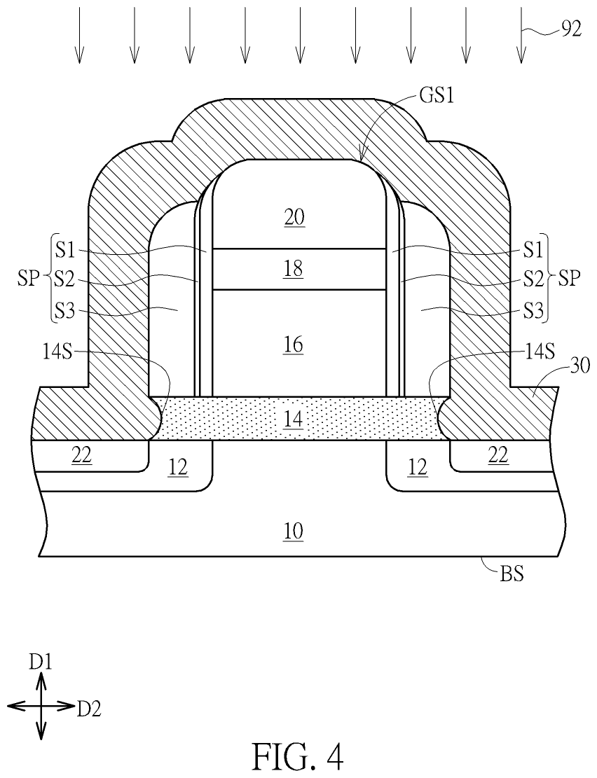

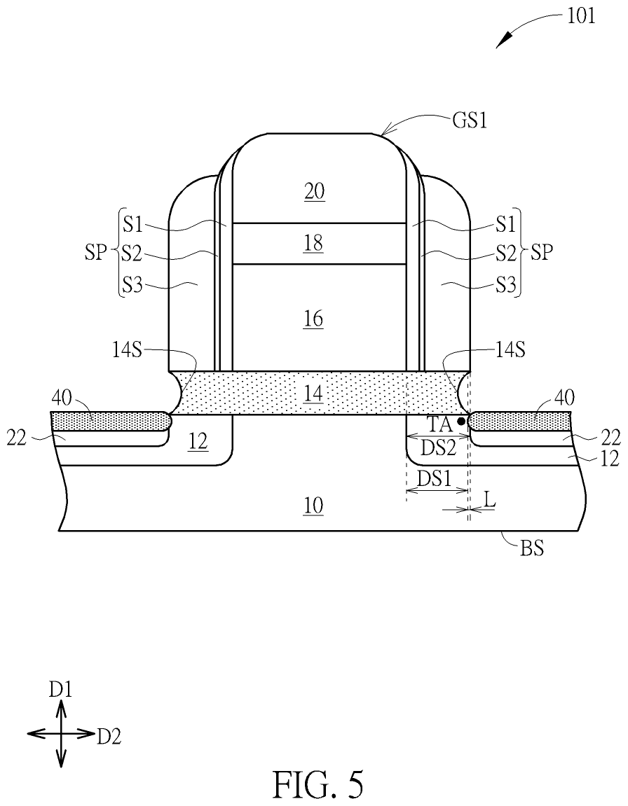

Please refer to FIGS. 1-5. FIG. 1 is a flow chart of a portion of a manufacturing method of a semiconductor device according to an embodiment of the present invention, and FIGS. 2-5 are schematic drawings illustrating a manufacturing method of a semiconductor device according to an embodiment of the present invention, wherein FIG. 3 is a schematic drawing in a step subsequent to FIG. 2, FIG. 4 is a schematic drawing in a step subsequent to FIG. 3, and FIG. 5 is a schematic drawing in a step subsequent to FIG. 4. The manufacturing method of the semiconductor device in this embodiment includes the following steps. As shown in FIG. 2, a semiconductor substrate 10 is provided, and a gate oxide layer 14, a gate structure GS1, and a spacer structure SP are formed on the semiconductor substrate 10. The gate oxide layer 14 is located between the gate structure GS1 and the semiconductor substrate 10 in a vertical direction D1, and the spacer structure SP is located on a sidewall of the gate structure GS1. Subsequently, a SiCoNi process 91 is performed, and a ratio of nitrogen trifluoride (NF₃) to ammonia (NH₃) used in the SiCoNi process 91, such as NF₃/NH₃, is greater than or equal to 0.35 and less than or equal to 0.4. As shown in FIGS. 2-5, after the SiCoNi process 91, a nickel silicide layer 40 is formed in the semiconductor substrate 10, and a part of the nickel silicide layer 40 is located under the spacer structure SP in the vertical direction D1. The range of the ratio of nitrogen trifluoride (NF₃) to ammonia (NH₃) used in the SiCoNi process may be controlled for suppressing lateral diffusion of the nickel silicide layer 40 formed in the subsequent process, and a distance (such as a distance DS1) between the nickel silicide layer 40 and the gate structure in a horizontal direction (such as a horizontal direction D2) may be controlled accordingly for avoiding negative influence caused by the distance between the nickel silicide layer 40 and the gate structure being too small, such as increasing the off current of the corresponding semiconductor device, but not limited thereto. Therefore, the purposes of improving the operation performance of the semiconductor device and/or enhancing the manufacturing yield may be achieved accordingly.

Specifically, the semiconductor substrate 10 may have a top surface and a bottom surface BS opposite to the top surface in the vertical direction D1. The vertical direction D1 may be regarded as a thickness direction of the semiconductor substrate 10, and the gate oxide layer 14, the gate structure GS1, and the spacer structure SP described above may be disposed at the side of the top surface. Horizontal directions substantially orthogonal to the vertical direction D1 (such as a horizontal direction D2 and other directions orthogonal to the vertical direction D1) may be substantially parallel with the top surface and/or the bottom surface BS of the semiconductor substrate 10, but not limited thereto. In this description, a distance between the bottom surface BS of the semiconductor substrate 10 and a relatively higher location and/or a relatively higher part in the vertical direction D1 may be greater than a distance between the bottom surface BS of the semiconductor substrate 10 and a relatively lower location and/or a relatively lower part in the vertical direction D1. The bottom or a lower portion of each component may be closer to the bottom surface BS of the semiconductor substrate 10 in the vertical direction D1 than the top or upper portion of this component. Another component disposed above a specific component may be regarded as being relatively far from the bottom surface BS of the semiconductor substrate 10 in the vertical direction D1, and another component disposed under a specific component may be regarded as being relatively close to the bottom surface BS of the semiconductor substrate 10 in the vertical direction D1, but not limited thereto. It is worth noting that, in this description, a top surface of a specific component may include the topmost surface of this component in the vertical direction D1, and a bottom surface of a specific component may include the bottommost surface of this component in the vertical direction D1, but not limited thereto. In this description, the condition that a certain component is disposed between two other components in a specific direction may include a condition that the certain component is sandwiched between the two other components in the specific direction.

As shown in FIG. 2, in some embodiments, two lightly doped regions 12 may be formed in the semiconductor substrate 10, and two source/drain doped regions 22 may be formed in the semiconductor substrate 10 and located in the lightly doped regions 12, respectively. The semiconductor substrate 10 may include a silicon substrate, an epitaxial silicon substrate, a silicon germanium substrate, a silicon carbide substrate, a silicon-on-insulator (SOI) substrate, or a substrate made of other suitable semiconductor materials. The lightly doped region 12 and the source/drain doped region 22 may be doped regions formed in the semiconductor substrate 10 by doping processes (such as implantation processes). The dopant type and/or the doping condition of each doped region may be adjusted according to the type of the corresponding semiconductor device (such as transistor) or other design considerations, and the dopant concentration of the lightly doped region 12 is lower than that of the source/drain doped region 22. In some embodiments, the lightly doped regions 12 may be formed in the semiconductor substrate 10 before the step of forming the gate oxide layer 14, and the source/drain regions 22 may be formed in the semiconductor substrate 10 after the steps of forming the gate oxide layer 14, the gate structure GS1, and the spacer structure SP, but not limited thereto. The gate oxide layer 14 may include silicon oxide or other suitable oxide dielectric materials, and the gate oxide layer 14 may be formed by an oxidation process, a deposition process, or other suitable approaches. The oxidation process described above may include a thermal oxidation process (such as rapid thermal oxidation, RTO), an in-situ-steam-generation (ISSG) process, or other suitable oxidation approaches, and the deposition process described above may include atomic layer deposition (ALD) or other suitable deposition approaches.

In some embodiments, the two lightly doped regions 12 may be located at two opposite sides of the gate oxide layer 14 in the horizontal direction D2, and a part of each of the lightly doped regions 12 may be located under the gate oxide layer 14 in the vertical direction D1. In addition, the two source/drain doped regions 22 may be located at two opposite sides of the gate oxide layer 14 in the horizontal direction D2, and an edge of the source/drain doped region 22 may be substantially aligned with an edge of the gate oxide layer 14, but not limited thereto. In some embodiments, the gate structure GS1 may include a polysilicon layer 16, a first mask layer 18, and a second mask layer 20 sequentially stacked in the vertical direction D1. The material composition of the first mask layer 18 is different from that of the second mask layer 20. For instance, the first mask layer 18 and the second mask layer 20 may be silicon nitride and tetraethoxysilane (TEOS), respectively, but not limited thereto. In addition, the spacer structure SP may include a first spacer S1, a second spacer S2, and a third spacer S3 disposed sequentially from the sidewall of the gate structure GS1 outwards in the horizontal direction. The materials of the first spacer S1, the second spacer S2, and the third spacer S3 may include silicon carbonitride, oxide (such as silicon oxide), and silicon nitride, respectively, or other suitable insulation materials. In some embodiments, a sidewall of the spacer structure SP (such as a sidewall of the third spacer S3) may be substantially aligned with an edge and/or a sidewall of the gate oxide layer 14, but not limited thereto.

As shown in FIG. 2, after the steps of forming the gate oxide layer 14, the gate structure GS1, the spacer structure SP, and the source/drain doped regions 22, an oxide layer 24 may be formed on the exposed surface of the semiconductor substrate 10 (such as being formed on the source/drain doped regions 22), and the oxide layer 24 may be regarded as an oxide layer formed by the influence of the environment (such as native oxide), but not limited thereto. In some embodiments, FIG. 1 may be regarded as a flow chart of a method of forming the nickel silicide layer described above, but not limited thereto. As shown in FIG. 1 and FIG. 2, a step S11 may be carried out for performing the SiCoNi process 91, and the SiCoNi process 91 is used to clean the semiconductor substrate 10. As shown in FIG. 2 and FIG. 3, the oxide layer 24 may be removed by the SiCoNi process 91, and a part of the gate oxide layer 14 may be removed by the SiCoNi process 91 for forming a sidewall 14S. In some embodiments, the sidewall 14S of the gate oxide layer 14 may include a C-shaped structure after the SiCoNi process 91 in a cross-sectional diagram of the semiconductor device, but not limited thereto. Subsequently, as shown in FIG. 1 and FIG. 4, a step S12 may be carried out for forming a metal layer 30 covering the semiconductor substrate 10. In some embodiments, the metal layer 30 may cover and contact the source/drain doped regions 22, the sidewall 14S of the gate oxide layer 14, the spacer structure SP, and the gate structure GS1, but not limited thereto. The metal layer 30 may include a single layer or multiple layers of metallic materials, such as a nickel layer, a nickel platinum (NiPt) layer, or a laminated structure composed of a nickel platinum layer and a titanium nitride layer, but not limited thereto. After the metal layer 30 is formed, a step S13 may be carried out for performing a thermal process 92, and the thermal process 92 may include a rapid thermal processing (RTP) or other suitable thermal processing approaches. As shown in FIG. 4 and FIG. 5, the nickel silicide layer 40 described above may be formed by the thermal process 92. The nickel silicide layer 40 may be formed by interdiffusion between the metal layer 30 and the semiconductor substrate 10, and at least a part of the nickel silicide layer 40 may be formed in the semiconductor substrate 10 (such as being formed in the source/drain doped regions 22) accordingly. The top surface of the nickel silicide layer 40 may be slightly higher than the top surface of the semiconductor substrate 10 in the vertical direction D1, and a part of the nickel silicide layer 40 may be located under the spacer structure SP and the gate oxide layer 14 in the vertical direction D1.

Subsequently, as shown in FIG. 1, FIG. 4, and FIG. 5, after the thermal process 92 and the step of forming the nickel silicide layer 40, a step S14 may be carried out for removing the metal layer 30. In some embodiments, after the step of removing the metal layer 30, a step S15 may be carried out for performing an annealing process to the nickel silicide layer 40, and a semiconductor device 101 may be formed accordingly. In some embodiments, before the step of forming the metal layer 30 and before the SiCoNi process 91, a patterned mask layer (not illustrated) may be formed covering the part of the semiconductor substrate 10 where the nickel silicide layer 40 does not need to be formed, and the patterned mask layer may be removed or remain on the semiconductor substrate 10 after the step of forming the nickel silicide layer 40. In some embodiments, the SiCoNi process 91 in FIG. 2 may be regarded as a step in the method of forming the nickel silicide layer 40, such as a pre clean process of the step of forming the metal layer 30 and/or a pre clean process performed before the step of forming the metal layer 30. In the SiCoNi process 91, a chemical etching may be carried out to oxide (such as silicon oxide) by using nitrogen trifluoride and ammonia, solid matters (such as ammonium hexafluorosilicate, (NH₄)₂SiF₆) will be generated in this etching, and the solid matters may be volatilized by a thermal treatment (such as an annealing step) to achieve the etching effect. It is worth noting that the fluorine concentration in the semiconductor substrate 10 formed by the influence of the SiCoNi process may be increased relatively by controlling the range of the ratio of nitrogen trifluoride to ammonia used in the SiCoNi process according to the manufacturing method in the present invention. Trapping sites for nickel atoms may be provided by the fluorine in the semiconductor substrate 10 for avoiding excessive diffusion of the nickel atoms in the semiconductor substrate 10 during the step of the forming the nickel silicide layer 40 described above, and the formation of the nickel silicide layer 40 may be controlled accordingly.

In some embodiments, the required nickel silicide layer 40 (such as a nickel silicide layer 40 with a specific thickness) cannot be formed because of excessive fluorine into the semiconductor substrate 10. Therefore, the ratio of nitrogen trifluoride to ammonia (NF₃/NH₃) used in the SiCoNi process 91 may be greater than or equal to 0.35 and less than or equal to 0.4, and the ratio (NF₃/NH₃) may be greater than or equal to 0.38 and less than or equal to 0.4 preferably, but not limited thereto. Additionally, in some embodiments, the ratio of nitrogen trifluoride to ammonia used in the SiCoNi process 91 may include a ratio of a gas flow rate of nitrogen trifluoride to a gas flow rate of ammonia in the SiCoNi process, and the gas flow rate described above may include a gas mass flow rate or other suitable calculation approaches. In addition, the fluorine concentration within a region located in the semiconductor substrate 10 and adjacent to the nickel silicide layer 40 may be increased by the manufacturing method of this embodiment for suppressing the excessive diffusion of the nickel atoms in the semiconductor substrate 10. For example, a fluorine concentration within a region located in the semiconductor substrate 10 and adjacent to the nickel silicide layer 40 (such as region TA) may be greater than or equal to 2.5 atomic percent (at %) and less than or equal to 4.5 atomic percent, and the fluorine concentration within the region TA may be greater than or equal to 3 atomic percent and less than or equal to 4 atomic percent preferably, but not limited thereto.

As shown in FIG. 5, the semiconductor device 101 in this embodiment includes the semiconductor substrate 10, the gate structure GS1, the gate oxide layer 14, the spacer structure SP, and the nickel silicide layer 40. The gate structure GS1 is disposed on the semiconductor substrate 10. The gate oxide layer 14 is disposed between the gate structure GS1 and the semiconductor substrate 10 in the vertical direction D1, and the spacer structure SP is disposed on the sidewall of the gate structure GS1. The nickel silicide layer 40 is disposed in the semiconductor substrate 10, a part of the nickel silicide layer 40 is located under the spacer structure SP in the vertical direction D1, and a length L of the part of the nickel silicide layer 40 located under the spacer structure SP in a horizontal direction (such as the horizontal direction D2) is greater than or equal to 4 nanometers and less than or equal to 5 nanometers.

In some embodiments, the semiconductor device 101 may further include the lightly doped regions 12 and the source/drain doped regions 22 described above. A thickness of the gate oxide layer 14 in the vertical direction D1 may be equal to about 20 nanometers, and the semiconductor device 101 may be regarded as a middle voltage (MV) transistor structure, such as a transistor structure with an operation voltage of approximately 8 volts, but not limited thereto. Additionally, in some embodiments, the distance DS1 between the nickel silicide layer 40 and the gate structure GS1 in the horizontal direction D2 may be greater than 21 nanometers, the distance DS1 may be greater than the thickness of the gate oxide layer 14 in the vertical direction D1, and the distance DS1 may be less than the thickness of the spacer structure SP in the horizontal direction D2 for controlling the position of the nickel silicide layer 40 and avoiding negative influence of an overextended nickel silicide layer 40 (such as causing the off current (I_{off}) of the semiconductor device 101 to be too high), but not limited thereto. In addition, the sidewall 14S of the gate oxide layer 14 may include a C-shaped structure in a cross-sectional diagram of the semiconductor device 101, and a width of a middle portion of the gate oxide layer 14 in the vertical direction D1 (such as a length of the middle portion in the horizontal direction D2) may be less than a width of a top portion of the gate oxide layer 14 in the vertical direction D1 and a width of a bottom portion of the gate oxide layer 14 in the vertical direction D1 accordingly. The sidewall 14S of the gate oxide layer 14 may be located between the spacer structure SP and the semiconductor substrate 10 in the vertical direction D1, and the sidewall 14S of the gate oxide layer 14 may be regarded as a concave structure, such as an inwardly concave structure in the horizontal direction. In addition, a part of the nickel silicide layer 40 may be located under the gate oxide layer 14 in the vertical direction D1, such as being located under the sidewall 14S of the gate oxide layer 14 in the vertical direction D1, and a length of the part of the nickel silicide layer 40 located under the gate oxide layer 14 in the horizontal direction (such as a length substantially equal to the length L described above) may be greater than or equal to 4 nanometers and less than or equal to 5 nanometers, but not limited thereto.

In some embodiments, by the influence of the manufacturing method described above, the source/drain doped regions 22 may be disposed in the semiconductor substrate 10 and located under the nickel silicide layer 40 in the vertical direction D1, and a distance DS2 between the source/drain doped region 22 and the gate structure GS1 in the horizontal direction D2 may be greater than the distance DS1 between the nickel silicide layer 40 and the gate structure GS1 in the horizontal direction D2, but not limited thereto. In some embodiments, the distance DS2 between the source/drain doped region 22 and the gate structure GS1 in the horizontal direction D2 may be substantially equal to the thickness of the spacer structure SP in the horizontal direction D2, but not limited thereto. In addition, the fluorine concentration within the region TA located in the semiconductor substrate 10 and adjacent to the nickel silicide layer 40 may be greater than or equal to 2.5 atomic percent and less than or equal to 4.5 atomic percent, and this fluorine concentration may be greater than or equal to 3 atomic percent and less than or equal to 4 atomic percent preferably. In some embodiments, the region TA may be located under the sidewall 14S of the gate oxide layer 14 in the vertical direction D1, the region TA may be located in the lightly doped region 12, and the region TA may be higher than an interface between the source/drain doped region 22 and the nickel silicide layer 40 in the vertical direction D1, but not limited thereto.

The following description will detail the different embodiments of the present invention. To simplify the description, identical components in each of the following embodiments are marked with identical symbols. For making it easier to understand the differences between the embodiments, the following description will detail the dissimilarities among different embodiments and the identical features will not be redundantly described.

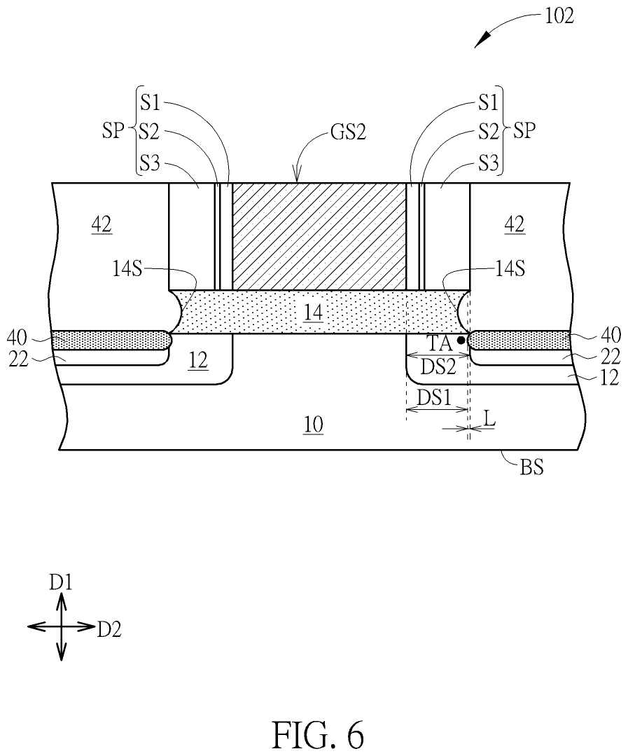

Please refer to FIG. 6 and FIG. 5. FIG. 6 is a schematic drawing illustrating a semiconductor device according to another embodiment of the present invention. In some embodiments, FIG. 6 may be regarded as a schematic drawing in a step subsequent to FIG. 5, but not limited thereto. As shown in FIG. 5 and FIG. 6, in some embodiments, after the step of forming the nickel silicide layer 40, a dielectric layer 42 may be formed covering the nickel silicide layer 40, the gate oxide layer 14, the gate structure GS1, and the spacer structure SP. The dielectric layer 42 may include an etching stop material and a dielectric material located on the etching stop material. The etching stop material may include silicon nitride or other suitable insulation materials, and the dielectric material may include silicon oxide or other dielectric materials different from the etching stop material. A planarization process may then be performed for removing a part of the dielectric layer 42, a part of the spacer structure SP, the second mask layer 20 and the first mask layer 18 and exposing the polysilicon layer 16. Subsequently, the polysilicon layer 16 may be replaced with a gate structure GS2 for forming a semiconductor device 102 illustrated in FIG. 6. In some embodiments, the gate structure GS2 may include electrically conductive metallic materials, such as a metal gate structure composed of a work function layer and a low electrical resistivity layer stacked on the work function layer. The low electrical resistivity layer may include a material with relative low electrical resistivity, such as copper, aluminum, tungsten, and so forth, and the work function layer may include titanium nitride, tantalum nitride, or other suitable work function materials. In this embodiment, the gate structure GS2 may be formed after the step of forming the nickel silicide layer 40, and the gate structure GS2 may be regarded as a gate structure formed by a replacement metal gate (RMG) process, but not limited thereto.

To summarize the above descriptions, according to the semiconductor device and the manufacturing method thereof in the present invention, the range of the ratio of nitrogen trifluoride to ammonia used in the SiCoNi process may be controlled for forming the required nickel silicide layer and suppressing the lateral diffusion of the nickel silicide layer. The distance between the nickel silicide layer and the gate structure in the horizontal direction may be controlled accordingly for avoiding the negative influence caused by the distance between the nickel silicide layer and the gate structure being too small. Therefore, the purposes of improving the operation performance of the semiconductor device (such as reducing the off current) and/or enhancing the manufacturing yield may be achieved accordingly.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A manufacturing method of a semiconductor device, comprising:
providing a semiconductor substrate;
forming a gate oxide layer, a gate structure, and a spacer structure on the semiconductor substrate, wherein the gate oxide layer is located between the gate structure and the semiconductor substrate in a vertical direction, and the spacer structure is located on a sidewall of the gate structure;
performing a SiCoNi process, wherein a ratio of nitrogen trifluoride (NF₃) to ammonia (NH₃) used in the SiCoNi process is greater than or equal to 0.35 and less than or equal to 0.4; and
forming a nickel silicide layer in the semiconductor substrate after the SiCoNi process, wherein a part of the nickel silicide layer is located under the spacer structure in the vertical direction.

2. The manufacturing method of the semiconductor device according to claim 1, wherein the ratio of nitrogen trifluoride to ammonia used in the SiCoNi process is greater than or equal to 0.38 and less than or equal to 0.4.

3. The manufacturing method of the semiconductor device according to claim 1, wherein the ratio of nitrogen trifluoride to ammonia used in the SiCoNi process comprises a ratio of a gas flow rate of nitrogen trifluoride to a gas flow rate of ammonia in the SiCoNi process.

4. The manufacturing method of the semiconductor device according to claim 1, wherein a method of forming the nickel silicide layer comprises:
forming a metal layer covering the semiconductor substrate;
performing a thermal process after the metal layer is formed; and
removing the metal layer after the thermal process, wherein the SiCoNi process is a pre clean process of the step of forming the metal layer.

5. The manufacturing method of the semiconductor device according to claim 1, wherein a part of the gate oxide layer is removed by the SiCoNi process.

6. The manufacturing method of the semiconductor device according to claim 5, wherein a sidewall of the gate oxide layer comprises a C-shaped structure after the SiCoNi process in a cross-sectional diagram of the semiconductor device.

7. The manufacturing method of the semiconductor device according to claim 1, wherein a fluorine concentration within a region located in the semiconductor substrate and adjacent to the nickel silicide layer is greater than or equal to 2.5 atomic percent (at %) and less than or equal to 4.5 atomic percent.

8. The manufacturing method of the semiconductor device according to claim 7, wherein the fluorine concentration within the region located in the semiconductor substrate and adjacent to the nickel silicide layer is greater than or equal to 3 atomic percent and less than or equal to 4 atomic percent.

9. The manufacturing method of the semiconductor device according to claim 1, wherein a length of the part of the nickel silicide layer located under the spacer structure in a horizontal direction is greater than or equal to 4 nanometers and less than or equal to 5 nanometers.

10. The manufacturing method of the semiconductor device according to claim 1, wherein a distance between the nickel silicide layer and the gate structure in a horizontal direction is greater than 21 nanometers.

11. A semiconductor device, comprising:
a semiconductor substrate;
a gate structure disposed on the semiconductor substrate;
a gate oxide layer disposed between the gate structure and the semiconductor substrate in a vertical direction;
a spacer structure disposed on a sidewall of the gate structure; and
a nickel silicide layer disposed in the semiconductor substrate, wherein a part of the nickel silicide layer is located under the spacer structure in the vertical direction, and a length of the part of the nickel silicide layer in a horizontal direction is greater than or equal to 4 nanometers and less than or equal to 5 nanometers.

12. The semiconductor device according to claim 11, wherein a sidewall of the gate oxide layer comprises a C-shaped structure in a cross-sectional diagram of the semiconductor device.

13. The semiconductor device according to claim 12, wherein the sidewall of the gate oxide layer is located between the spacer structure and the semiconductor substrate in the vertical direction.

14. The semiconductor device according to claim 11, wherein a part of the nickel silicide layer is located under a sidewall of the gate oxide layer in the vertical direction.

15. The semiconductor device according to claim 11, wherein a sidewall of the gate oxide layer is a concave structure.

16. The semiconductor device according to claim 11, wherein a fluorine concentration within a region located in the semiconductor substrate and adjacent to the nickel silicide layer is greater than or equal to 2.5 atomic percent (at %) and less than or equal to 4.5 atomic percent.

17. The semiconductor device according to claim 16, wherein the fluorine concentration within the region located in the semiconductor substrate and adjacent to the nickel silicide layer is greater than or equal to 3 atomic percent and less than or equal to 4 atomic percent.

18. The semiconductor device according to claim 11, wherein a part of the nickel silicide layer is located under the gate oxide layer in the vertical direction, and a length of the part of the nickel silicide layer located under the gate oxide layer in the horizontal direction is greater than or equal to 4 nanometers and less than or equal to 5 nanometers.

19. The semiconductor device according to claim 11, wherein a distance between the nickel silicide layer and the gate structure in the horizontal direction is greater than 21 nanometers.

20. The semiconductor device according to claim 11, further comprising:
a source/drain doped region disposed in the semiconductor substrate and located under the nickel silicide layer, wherein a distance between the source/drain doped region and the gate structure in the horizontal direction is greater than a distance between the nickel silicide layer and the gate structure in the horizontal direction.
